(19) United States
(12) Patent Application Publication
(10) Pub. No.: US 2025/0279343 A1
(43) Pub. Date: Sep. 4, 2025

(54) CERAMIC SUBSTRATE, METHOD FOR MANUFACTURING CERAMIC SUBSTRATE, LIGHT-EMITTING DEVICE, AND METHOD FOR MANUFACTURING LIGHT-EMITTING DEVICE

(71) Applicant: NICHIA CORPORATION, Anan-shi (JP)

(72) Inventor: Takashi KAWAMATA, Tokushima-shi (JP)

(73) Assignee: NICHIA CORPORATION, Anan-shi (JP)

(21) Appl. No.: 19/063,290

(22) Filed: Feb. 26, 2025

(30) Foreign Application Priority Data
Feb. 29, 2024 (JP) 2024-030748

(51) Int. Cl. H01L 23/498; H01L 21/48; H01L 23/15; H10H 20/85

(52) U.S. Cl. CPC H01L 23/49827; H01L 21/486; H01L 23/49894; H10H 20/8508; H01L 23/15

(57) ABSTRACT

A method for manufacturing a ceramic substrate including forming a through hole or a recessed portion in a ceramic plate containing aluminum nitride and having a first surface and a second surface opposite to the first surface by irradiating the ceramic plate with a laser so that aluminum is precipitated, removing the aluminum precipitated on an inner surface of the through hole or the recessed portion, and disposing a conductive paste inside the through hole or the recessed portion.

### CROSS-REFERENCE TO RELATED APPLICATIONS

The present application claims priority under 35 U.S.C. § 119 to Japanese Patent Application No. 2024-030748, filed Feb. 29, 2024, the contents of which are hereby incorporated by reference in their entirety.

### BACKGROUND

### 1. Technical Field

The present disclosure relates to a ceramic substrate, a method for manufacturing the ceramic substrate, a light-emitting device, and a method for manufacturing the light-emitting device.

### 2. Description of Related Art

In recent years, a substrate has been proposed in which in order to achieve miniaturization, high functionality, and integration of electronic devices or components, a through hole (also referred to as a “hole part”, a “via”, or the like) is formed in an insulating substrate and a conductive material such as copper or silver is disposed in the through hole in order to electrically conduct both surfaces of the substrate to each other. For example, there is known a via-filled substrate including an insulating substrate provided with a hole part and a conducting via part formed of a conductor filled in the hole part, in which the conducting via part has a porosity of 10 vol % or less, substantially no gap exists between the conducting via part and a wall face of the hole part, and the conducting via part is formed of a conducting via body having a sea island structure including continuous phases and dispersal phases and an active metal film present at an interface with the hole part wall face (see, for example, Japanese Patent Publication No. 2022-13766).

### SUMMARY

Embodiments of the present disclosure can provide a highly reliable ceramic substrate in which adhesion between a ceramic plate and a conductive member inside a through hole or a recessed portion of the ceramic plate can be improved and migration of a metal in the conductive member can be suppressed, a method for manufacturing the ceramic substrate, a light-emitting device, and a method for manufacturing the light-emitting device.

A method for manufacturing a ceramic substrate according to an embodiment of the present disclosure includes forming a through hole or a recessed portion in a ceramic plate containing aluminum nitride and having a first surface and a second surface opposite to the first surface by irradiating the ceramic plate with a laser so that aluminum is precipitated; removing the aluminum precipitated on an inner surface of the through hole or the recessed portion; and disposing a conductive paste inside the through hole or the recessed portion.

A ceramic substrate according to an embodiment of the present disclosure includes a ceramic plate containing aluminum nitride and having a first surface, a second surface opposite to the first surface, and a through hole connecting the first surface and the second surface or a recessed portion in at least one of the first surface and the second surface; and a conductive member formed inside the through hole or the recessed portion, in which in the through hole or the recessed portion, an inner surface defining the through hole or the recessed portion is provided with a nitride coating film having an average thickness in a range from 10 μm to 35 μm.

A method for manufacturing a light-emitting device according to an embodiment of the present disclosure includes preparing the ceramic substrate manufactured by the method for manufacturing a ceramic substrate according to an embodiment of the present disclosure; and disposing a light-emitting element including an electrode over the ceramic substrate, in which the electrode and the conductive member are electrically connected to each other.

A light-emitting device according to an embodiment of the present disclosure includes the ceramic substrate according to an embodiment of the present disclosure; and a light-emitting element disposed over the ceramic substrate and including an electrode, in which the electrode and the conductive member are electrically connected to each other.

An embodiment of the present disclosure can provide a highly reliable ceramic substrate in which adhesion between a ceramic plate and a conductive member inside a through hole or a recessed portion of the ceramic plate can be improved and migration of a metal in the conductive member can be suppressed, a method for manufacturing the ceramic substrate, a light-emitting device, and a method for manufacturing the light-emitting device.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1A is a schematic top view illustrating an example of a ceramic substrate according to a first embodiment.

FIG. 1B is a schematic bottom view illustrating an example of the ceramic substrate according to the first embodiment.

FIG. 1C is a schematic cross-sectional view illustrating a cross section taken along line IC-IC in FIGS. 1A and 1B.

FIG. 2 is a schematic cross-sectional view illustrating a modified example of the ceramic substrate according to the first embodiment.

FIG. 3A is a schematic top view illustrating an example of a ceramic substrate according to a second embodiment.

FIG. 3B is a schematic bottom view illustrating an example of the ceramic substrate according to the second embodiment.

FIG. 3C is a schematic cross-sectional view illustrating a cross section taken along line IIIC-IIIC in FIGS. 3A and 3B.

FIG. 4 is a schematic cross-sectional view illustrating a modified example of the ceramic substrate according to the second embodiment.

FIG. 5 is a flowchart showing an example of a method for manufacturing the ceramic substrate according to the first embodiment.

FIG. 6A is a schematic cross-sectional view illustrating an example of a ceramic plate used in the method for manufacturing the ceramic substrate according to the first embodiment.

FIG. 6B is a schematic cross-sectional view illustrating an example of forming a through hole in the method for manufacturing the ceramic substrate according to the first embodiment.

FIG. 6C is a schematic cross-sectional view illustrating an example of removing precipitated aluminum in the method for manufacturing the ceramic substrate according to the first embodiment.

FIG. 6D is a schematic cross-sectional view illustrating an example of polishing or grinding the ceramic plate in the method for manufacturing the ceramic substrate according to the first embodiment.

FIG. 6E is a schematic cross-sectional view illustrating an example of disposing a conductive paste in the method for manufacturing the ceramic substrate according to the first embodiment.

FIG. 6F is a schematic cross-sectional view illustrating an example of forming a conductive member in the method for manufacturing the ceramic substrate according to the first embodiment.

FIG. 6G is a schematic cross-sectional view illustrating an example of polishing or grinding the conductive member in the method for manufacturing the ceramic substrate according to the first embodiment.

FIG. 7A is an enlarged cross-sectional view schematically illustrating a region VIIA in FIG. 6E.

FIG. 7B is an enlarged cross-sectional view schematically illustrating a region VIIB in FIG. 6F.

FIG. 8 is a schematic cross-sectional view illustrating an example of a light-emitting device according to an embodiment.

FIG. 9A is a perspective view illustrating an application example of the light-emitting device according to the embodiment.

FIG. 9B is a cross-sectional view illustrating a cross section taken along line IXB-IXB in FIG. 9A.

FIG. 10 is a flowchart showing an example of a method for manufacturing the light-emitting device according to the embodiment.

FIG. 11A is a cross-sectional observation image of a through hole after laser irradiation in forming a through hole in a first example.

FIG. 11B is a cross-sectional observation image of a through hole after etching in removing aluminum in the first example.

FIG. 12A is an observation image of a cross section of a ceramic substrate of the first example by a scanning electron microscope (SEM).

FIG. 12B is a fluorescent X-ray spectroscopic image (Ti-Kα) of a cross section of the ceramic substrate of the first example as an observation image thereof.

FIG. 13A is an observation image of a region including an inner surface defining a through hole in a first surface of the ceramic substrate of the first example by a metallurgical microscope.

FIG. 13B is an observation image of the region including the inner surface defining the through hole in the first surface of the ceramic substrate of the first example by a scanning electron microscope (SEM).

### DETAILED DESCRIPTION OF EMBODIMENT

A ceramic substrate, a method for manufacturing the ceramic substrate, a light-emitting device, and a method for manufacturing the light-emitting device according to embodiments of the present disclosure are described in detail with reference to the drawings. However, the following embodiments exemplify a ceramic substrate, a method for manufacturing the ceramic substrate, a light-emitting device, and a method for manufacturing the light-emitting device that embody the technical ideas of the present disclosure and are not limited to the following.

Further, dimensions, materials, shapes, relative arrangements, or the like of constituent members described in the embodiments are not intended to limit the scope of the present disclosure thereto, unless otherwise specified, and are merely exemplary. Note that the sizes, positional relationship, or the like of members illustrated in each of the drawings may be exaggerated for clarity of description. Further, in the following description, members having the same terms and reference characters represent the same members or members of the same quality, and a detailed description of these members will be omitted as appropriate. In order to avoid excessive complication of the drawings, a schematic view in which some elements are not illustrated may be used, or an end view illustrating only a cutting surface may be used as a cross-sectional view.

In the present disclosure, polygons such as rectangles, triangles, and quadrangles, including shapes in which the corners of the polygon are rounded, chamfered, beveled, coved, and the like, are referred to as polygons. Not only a shape obtained by processing the corners (ends of a side) but also a shape obtained by processing an intermediate portion of the side is similarly referred to as a polygon. That is, a shape that is partially processed while leaving the polygon as the base is included in the interpretation of the “polygon” described in the present disclosure.

The same applies not only to polygons but also to words representing specific shapes such as trapezoids, circles, protrusions, and recessions. The same applies when dealing with each side forming that shape. That is, even if processing is performed on a corner or an intermediate portion of a certain side, the interpretation of “side” includes the processed portion. When a “polygon” or a “side” not partially processed is to be distinguished from a processed shape, “strict” will be added to the description as in, for example, “strict quadrangle”.

In the following description, terms indicating a specific direction or position (for example, “upper”, “lower”, “X”, “Y”, “Z”, and other terms including those terms) are used as necessary. The use of those terms, however, is to facilitate understanding of the invention with reference to the drawings, and the technical scope of the present invention is not excessively limited by the meanings of those terms. For example, when “upper surface” is described, the invention does not always have to be used so as to face upward. Portions having the same reference signs appearing in a plurality of drawings indicate identical or equivalent portions or members. In the embodiments, “covering” includes not only a case of covering by direct contact but also a case of indirectly covering, for example, via another member.

In the present specification or appended claims, when there are a plurality of constituent components and those components are individually denoted, the constituent components may be distinguished by adding terms such as “first”, “second”, and the like in front of terms of the components.

### Ceramic Substrate

### First Embodiment

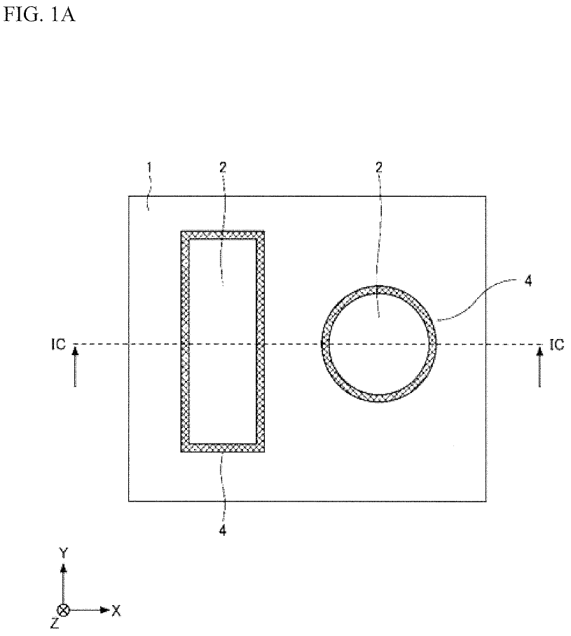

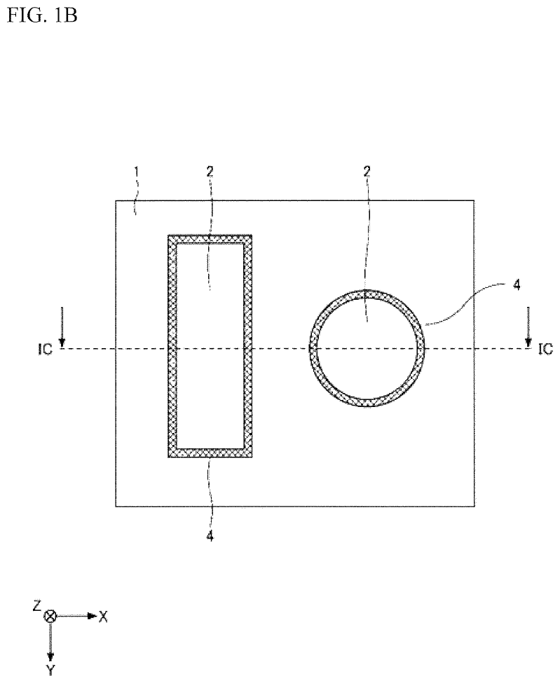

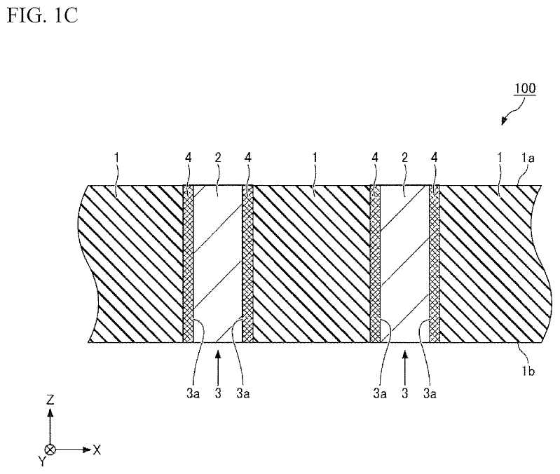

FIG. 1A is a schematic top view illustrating an example of a ceramic substrate according to the first embodiment. FIG. 1B is a schematic bottom view illustrating an example of the ceramic substrate according to the first embodiment. FIG. 1C is a schematic cross-sectional view illustrating a cross section taken along line IC-IC in FIGS. 1A and 1B. Components of a ceramic substrate 100 are described below.

The ceramic substrate 100 according to the first embodiment includes an aluminum nitride-containing ceramic plate 1 having a first surface 1a, a second surface 1b opposite to the first surface 1a, and a through hole 3 connecting the first surface 1a and the second surface 1b, and a conductive member 2 formed inside the through hole 3, and in the through hole 3, an inner surface 3a defining the through hole 3 is provided with a nitride coating film 4 having an average thickness in a range from 10 μm to 35 μm.

### Ceramic Plate 1

The ceramic plate 1 is an insulating member serving as a base for forming the conductive member 2. The ceramic plate 1 is a sintered plate, and is preferably one not in a softened state before sintering.

The ceramic plate 1 includes aluminum nitride. The ceramic plate 1 preferably includes aluminum nitride as a main material, and can further include other auxiliary materials as necessary. The “main material” means a material having the largest amount of substance among materials constituting the ceramic plate 1.

Examples of the auxiliary materials in the ceramic plate 1 are not particularly limited, and include ceramic other than aluminum nitride, and glass. These can be used alone or in combination of two or more.

Ceramic other than aluminum nitride is not particularly limited, and examples thereof include nitride-based ceramic such as silicon nitride and boron nitride; oxide-based ceramic such as aluminum oxide, silicon oxide, calcium oxide, and magnesium oxide; silicon carbide; mullite; and borosilicate glass. These can be used alone or in combination of two or more.

The ceramic plate 1 is preferably a plate-shaped member having a substantially rectangular outer shape in plan view. This rectangular shape can be a rectangular shape with long sides and short sides. A rectangular shape can include a square shape unless specifically described as excluding a square shape. The outer shape of the ceramic plate 1 in plan view is not limited to a rectangle, and can be a circle, an ellipse, a polygon, or the like.

The first surface 1a can be a flat surface or need not be a flat surface. However, when the ceramic substrate 100 is used in a light-emitting device, the first surface 1a is preferably a flat surface because light-emitting elements can be suitably disposed.

The second surface 1b is a surface on the opposite side to the first surface 1a in the ceramic plate 1. The second surface 1b can be a flat surface or need not be a flat surface. However, when the ceramic substrate 100 is used in a light-emitting device, the second surface 1b is preferably a flat surface in that the ceramic substrate 100 can be suitably disposed on a mounting substrate.

In the ceramic substrate 100 according to the first embodiment, a surface of the ceramic plate 1 on the upper side of FIG. 1C is denoted as the first surface 1a, and a surface of the ceramic plate 1 on the lower side of FIG. 1C is denoted as the second surface 1b; however, the first surface 1a and the second surface 1b are denoted separately only for convenience and when the ceramic substrate 100 is used in a light-emitting device, a mounting substrate can be disposed on the first surface 1a and light-emitting elements can be disposed on the second surface 1b.

The first surface 1a and the second surface 1b are parallel to each other, for example. When the surface of the ceramic plate 1 is described as being “parallel”, a difference within +5° is allowed.

The through hole 3 connects the first surface 1a and the second surface 1b. The through hole 3 is, for example, a via hole.

The shape of an opening of the through hole 3 in plan view of the ceramic plate 1 is preferably a circular or elliptical shape. The shape of the opening of the through hole 3 in plan view of the ceramic plate 1 is not limited to a circular or elliptical shape, and can be a polygonal shape, including a rectangular shape, or the like.

In the ceramic substrate 100 according to the first embodiment, the opening diameter of the opening of the through hole 3 formed in the first surface 1a and the opening diameter of the opening of the through hole 3 formed in the second surface 1b in plan view of the ceramic plate 1 are not particularly limited, and can be appropriately selected depending on the purpose. The opening diameters are each preferably in a range from 50 μm to 500 μm, more preferably in a range from 50 μm to 200 μm.

In the ceramic substrate 100 according to the first embodiment, the opening diameter of the through hole 3 formed in the first surface 1a of the ceramic plate 1 is the same as the opening diameter of the through hole 3 formed in the second surface 1b. When the opening diameters of the through holes 3 of the ceramic plate 1 are described as “the same”, a difference within +5% is allowed.

When the shape of the opening of the through hole 3 is a circular or elliptical shape, the “opening diameter” is the maximum diameter of the opening. When the shape of the opening of the through hole 3 in plan view of the ceramic plate 1 is a rectangular shape, the “opening diameter” is the length of a diagonal line of the opening.

The number of through holes 3 in the ceramic plate 1 is not particularly limited and can be one or plural, but is preferably plural from the viewpoint of being mounted in a light-emitting device.

When a plurality of through holes 3 are provided, the arrangement of the plurality of through holes 3 in plan view of the ceramic plate 1, the pitch between one through hole 3 and another adjacent through hole 3, and the like are not particularly limited and can be appropriately selected depending on the purpose.

In the through hole 3, the inner surface 3a defining the through hole 3 is provided with the nitride coating film 4 having an average thickness in a range from 10 μm to 35 μm. That is, the nitride coating film 4 is disposed at an interface between the conductive member 2 and the inner surface 3a defining the through hole 3. The nitride coating film 4 improves the adhesion between the ceramic plate 1 and the conductive member 2 formed inside the through hole 3, so that the ceramic substrate 100 having high reliability can be obtained.

The inner surface 3a defining the through hole 3 in the ceramic plate 1 has irregularities and is roughened. A recessed portion of the inner surface 3 a defining the through hole 3 is an irregular minute structure. In the present disclosure, the irregular minute structure of the recessed portion of the inner surface 3a defining the through hole 3 can be referred to as, for example, a root shape or a tree shape. Nitride is present in the recessed portion having a root shape. Accordingly, the nitride coating film 4 includes the inner surface 3a defining the through hole 3 having a root shape and the nitride present in the inner surface 3a. More specifically, the nitride coating film 4 includes a material of the ceramic plate 1 and nitride, and can further include a component derived from the conductive member 2.

An arithmetic mean roughness Ra of the inner surface 3a defining the through hole 3 is not particularly limited and can be appropriately selected depending on the purpose, but is preferably in a range from 1.0 μm to 3.5 μm. The arithmetic mean roughness Ra of the inner surface 3a defining the through hole 3 is measured in accordance with JIS B 0601 by using a stylus type surface roughness measuring instrument (for example, SE 3500 manufactured by Kosaka Laboratory Ltd.) equipped with a diamond stylus having a tip radius r of curvature of 2 μm.

Examples of the nitride in the nitride coating film 4 include titanium nitride.

The average thickness of the nitride coating film 4 is in a range from 10 μm to 35 μm, preferably in a range from 10 μm to 25 μm.

In the ceramic substrate 100 according to the first embodiment, the average thickness of the nitride coating film 4 is a value measured as follows. A scanning electron microscope (SEM) image is obtained by observing at least a part of the conductive member 2 and a region X including at least 50 μm in the depth direction of the recessed portion from the inner surface 3a defining the through hole 3 in the ceramic plate 1 at a magnification of 250 times in the thickness direction of the ceramic substrate 100 and in a cross section passing through the center of gravity of the opening of the through hole 3. In the SEM image of the region X, a maximum length 1 of a root-shaped recessed portion extending from the inner surface 3a defining the through hole 3 toward the ceramic plate 1 is measured. Similarly, the maximum length 1 is measured at five points arbitrarily selected from the ceramic substrate 100, and an average maximum length L of the five points is obtained. This average maximum length L is defined as the average thickness of the nitride coating film 4 in the ceramic substrate 100 according to the first embodiment.

The inner surface 3a defining the through hole 3 can be provided with the nitride coating film 4 discontinuously or continuously.

Being provided with the nitride coating film 4 “discontinuously” means that the nitride coating film 4 on the inner surface 3a defining the through hole 3 includes a region in which at least a part of the nitride coating film 4 is interrupted within the range of the average thickness of the nitride coating film 4. In this case, in the region in which the nitride coating film 4 is interrupted on the inner surface 3a defining the through hole 3, that is, in a region not including the nitride coating film 4, no nitride exists in the root-shaped recessed portion of the inner surface 3a defining the through hole 3.

When the inner surface 3a defining the through hole 3 is discontinuously provided with the nitride coating film 4, the region not including the nitride coating film 4 can include an aluminum film derived from the ceramic plate 1 on the inner surface 3a defining the through hole 3. In other words, when the inner surface 3a defining the through hole 3 is discontinuously provided with the nitride coating film 4, the inner surface 3a defining the through hole 3 can be provided with a discontinuous aluminum film. In this case, the inner surface 3a defining the through hole 3 includes a region including the nitride coating film 4 and a region including the aluminum film. Accordingly, when the inner surface 3a defining the through hole 3 is discontinuously provided with the nitride coating film 4, the inner surface 3a defining the through hole 3 is provided with no continuous aluminum film.

Being provided with the nitride coating film 4 “continuously” means that the nitride coating film 4 on the inner surface 3a defining the through hole 3 is disposed without interruption within the range of the average thickness of the nitride coating film 4. That is, when the inner surface 3a defining the through hole 3 is continuously provided with the nitride coating film 4, the inner surface 3a defining the through hole 3 is provided with no aluminum film derived from the ceramic plate 1.

### Conductive Member 2

The conductive member 2 is a member serving as electrical wiring in the ceramic substrate 100. The conductive member 2 is, for example, via. In the ceramic substrate 100 according to the first embodiment, the conductive member 2 is formed inside the through hole 3. The conductive member 2 is preferably formed flush with the first surface 1a of the ceramic plate 1 on the first surface 1a side and flush with the second surface 1b of the ceramic plate 1 on the second surface 1b side.

The conductive member 2 preferably contains a eutectic structure of silver and copper. The eutectic structure of the conductive member 2 can be confirmed by observing a cross section in the thickness direction of the ceramic substrate 100 including the cross section of the conductive member 2 by using an SEM.

The ceramic substrate 100 according to the first embodiment can be suitably manufactured by a method for manufacturing a ceramic substrate according to the first embodiment to be described below.

### Modified Example of First Embodiment

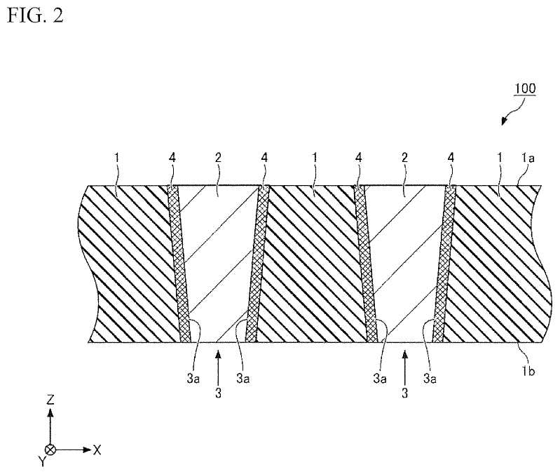

FIG. 2 is a schematic cross-sectional view illustrating a modified example of the ceramic substrate according to the first embodiment.

The modified example of the ceramic substrate 100 according to the first embodiment is different from the ceramic substrate 100 according to the first embodiment in that the opening diameter of the through hole 3 in the first surface 1a of the ceramic plate 1 is larger than the opening diameter of the through hole 3 in the second surface 1b. When the opening diameter of the through hole 3 of the ceramic plate 1 is described as “large”, it means that the opening diameter of the through hole 3 in the second surface 1b of the ceramic plate 1 is larger than the opening diameter of the through hole 3 in the first surface 1a of the ceramic plate 1 by more than 5%.

Although FIG. 2 illustrates an example in which the opening diameter of the through hole 3 in the first surface 1a of the ceramic plate 1 is larger than the opening diameter of the through hole 3 in the second surface 1b, the first surface 1a and the second surface 1b are merely illustrated in order to distinguish the surfaces in the drawing for the sake of convenience, and the opening diameter of the through hole 3 in the second surface 1b of the ceramic plate 1 can be larger than the opening diameter of the through hole 3 in the first surface 1a.

The ratio of the opening diameter of through hole 3 in the first surface 1a to the opening diameter of through hole 3 in the second surface 1b is not particularly limited.

### Second Embodiment

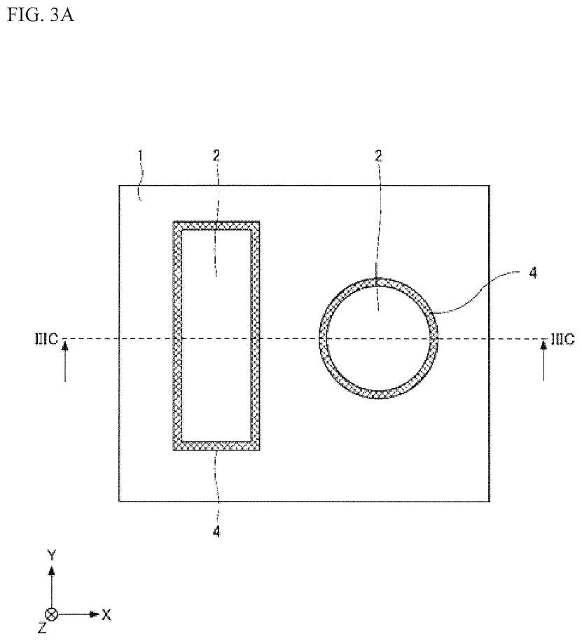

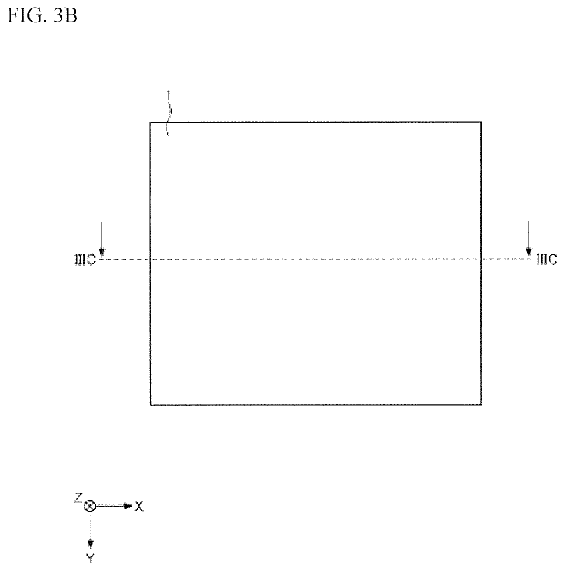

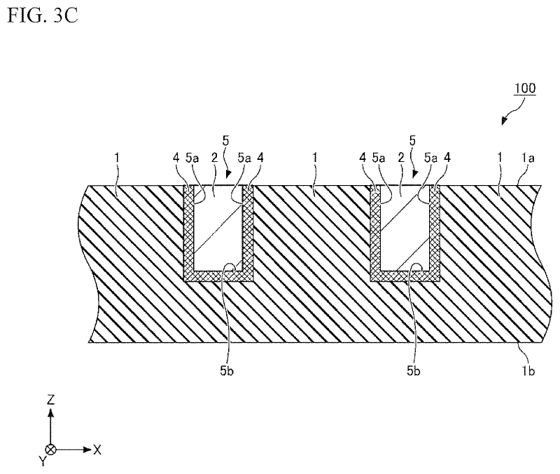

FIG. 3A is a schematic top view illustrating an example of a ceramic substrate according to a second embodiment. FIG. 3B is a schematic bottom view illustrating an example of the ceramic substrate according to the second embodiment. FIG. 3C is a schematic cross-sectional view illustrating a cross section taken along line IIIC-IIIC in FIGS. 3A and 3B.

A ceramic substrate 100 according to the second embodiment includes an aluminum nitride-containing ceramic plate 1 having a first surface 1a, a second surface 1b opposite to the first surface 1a, and a recessed portion 5 in at least one of the first surface 1a and the second surface 1b, and a conductive member 2 formed inside the recessed portion 5, and in the recessed portion 5, an inner surface defining the recessed portion 5 is provided with a nitride coating film 4 having an average thickness in a range from 10 μm to 35 μm.

FIG. 3A illustrates an example in which the first surface 1a is provided with a recessed portion 5, but the first surface 1a and the second surface 1b are merely illustrated in order to distinguish the surfaces in the drawing for the sake of convenience and the second surface 1b can be provided with the recessed portion 5.

The ceramic substrate 100 according to the second embodiment is different from the ceramic substrate 100 according to the first embodiment in that the through hole 3 is replaced with the recessed portion 5 in the ceramic substrate 100 according to the first embodiment, and the configuration other than the recessed portion 5 is the same as the configuration of the ceramic substrate 100 according to the first embodiment.

The recessed portion 5 is a bottomed hole that does not penetrate from the first surface 1a to the second surface 1b. The recessed portion 5 has a lateral surface 5a that connects an opening and a bottom 5b in a Z-axis direction and the bottom. That is, an inner surface defining the recessed portion 5 is composed of the lateral surface 5a and the bottom 5b of the recessed portion 5. The recessed portion 5 has the same configuration as the through hole 3 except that a cross-sectional shape in the Z-axis direction is different.

A maximum depth of the recessed portion 5, that is, a maximum length of the inner surface defining the recessed portion 5 in the Z-axis direction in cross-sectional view is not particularly limited and can be appropriately selected depending on the thickness of the ceramic plate 1, but is preferably in a range from 25 μm to 300 μm, more preferably in a range from 50 μm to 200 μm, still more preferably in a range from 50 μm to 100 μm.

### Modified Example of Second Embodiment

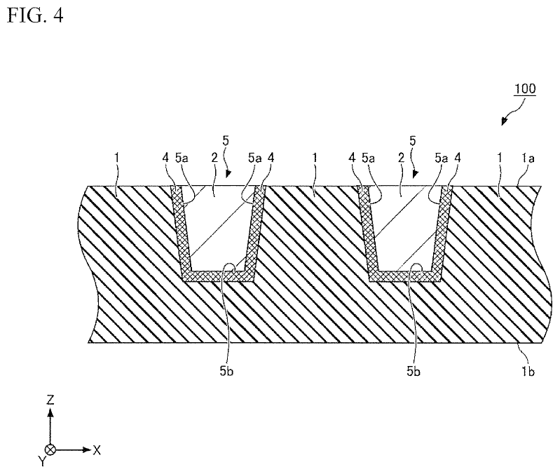

FIG. 4 is a schematic cross-sectional view illustrating a modified example of the ceramic substrate according to the second embodiment.

The modified example of the ceramic substrate 100 according to the second embodiment is different from the ceramic substrate 100 according to the first embodiment in that the opening diameter of the recessed portion 5 is larger than the bottom diameter of the bottom 5b of the recessed portion 5. When the opening diameter of the recessed portion 5 of the ceramic plate 1 is described as “large”, it means that the bottom diameter of the bottom 5b of the recessed portion 5 is larger than the opening diameter of the recessed portion 5 by more than 5%.

The ratio of the opening diameter of the recessed portion 5 to the bottom diameter of the bottom 5b of the recessed portion 5 is not particularly limited.

The cross-sectional shape of the recessed portion 5 of the ceramic substrate 100 according to the second embodiment in the Z-axis direction is not limited to a rectangle, and can be, for example, a triangle, a trapezoid, a U-shape, or the like.

### Method for Manufacturing Ceramic Substrate

### First Embodiment

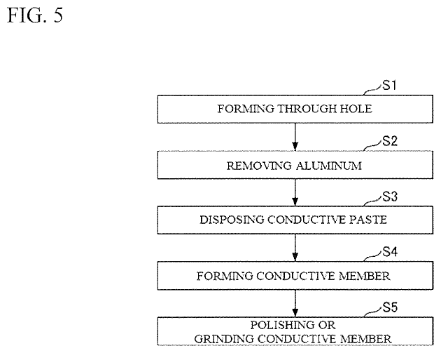

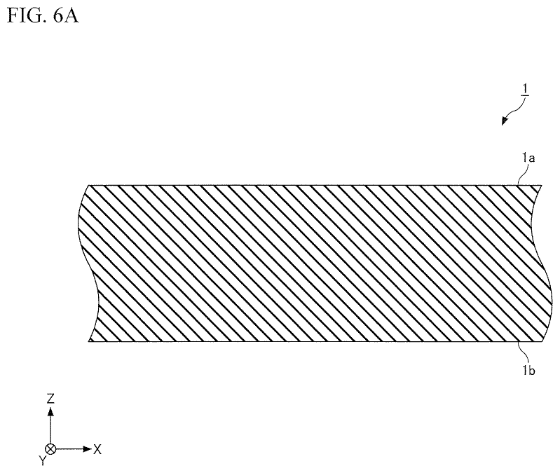

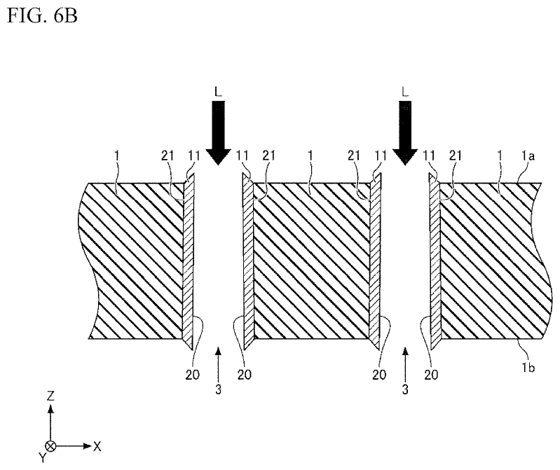

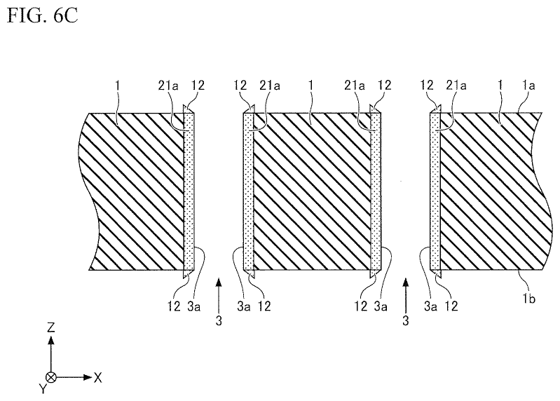

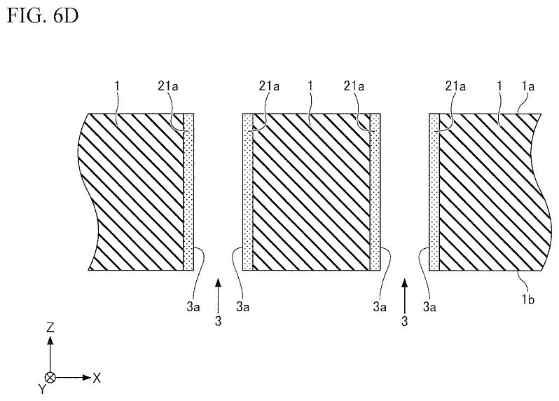

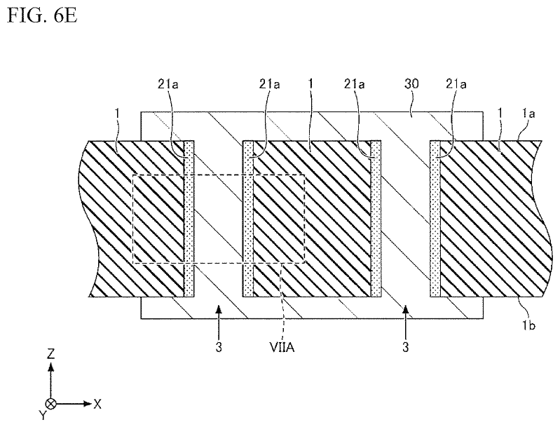

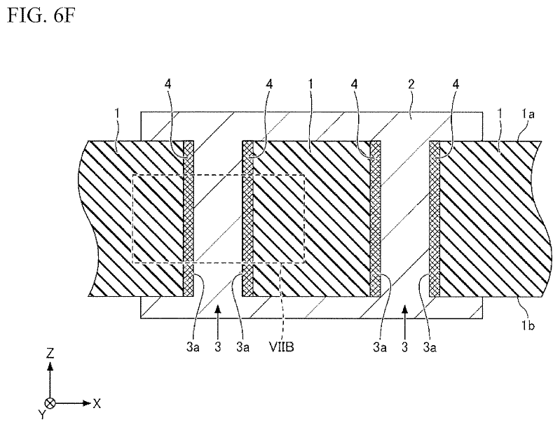

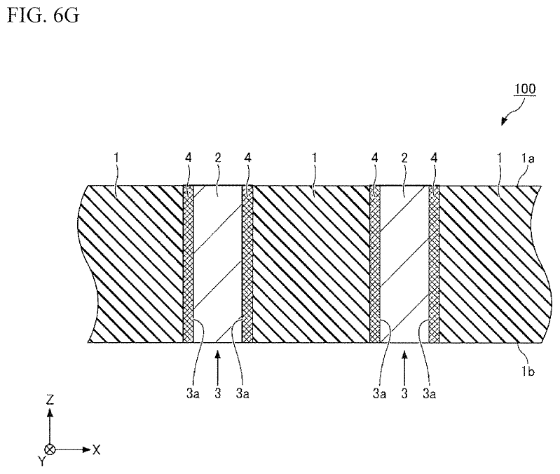

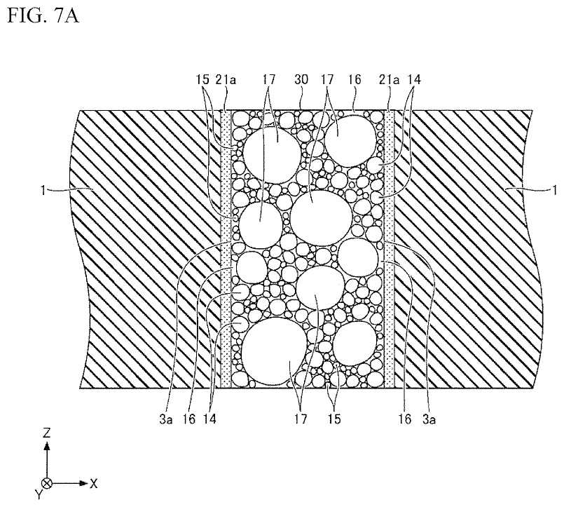

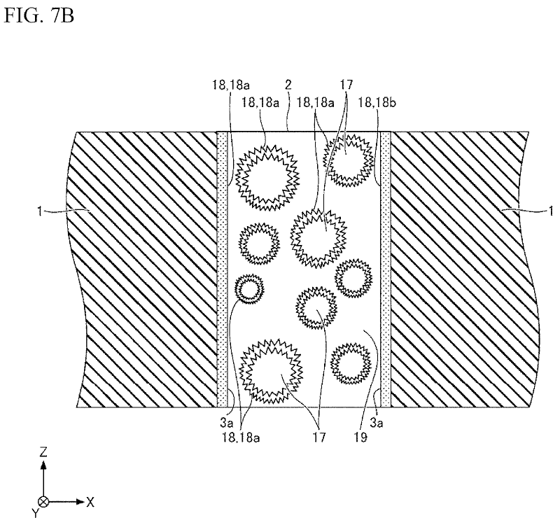

FIG. 5 is a flowchart showing an example of a method for manufacturing the ceramic substrate according to the first embodiment. The method for manufacturing the ceramic substrate according to the first embodiment is described with reference to FIGS. 6A to 6G and FIGS. 7A and 7B.

The method for manufacturing the ceramic substrate according to the first embodiment includes S1 of forming the through hole 3 in the aluminum nitride-containing ceramic plate 1 having the first surface 1a and the second surface 1b opposite to the first surface 1a by irradiating the ceramic plate 1 with a laser L so that aluminum 11 is precipitated, S2 of removing the aluminum 11 precipitated on the inner surface 3a defining the through hole 3, and S3 of disposing a conductive paste 30 inside the through hole 3. The method for manufacturing the ceramic substrate according to the first embodiment preferably further includes S2-1 of polishing or grinding the ceramic plate 1, S4 of forming the conductive member 2, and S5 of polishing or grinding the conductive member 2.

### S1: Forming Through Hole

FIG. 6A is a schematic cross-sectional view illustrating an example of the ceramic plate used in the method for manufacturing the ceramic substrate according to the first embodiment. FIG. 6B is a schematic cross-sectional view illustrating an example of forming the through hole in the method for manufacturing the ceramic substrate according to the first embodiment.

The ceramic plate 1 including aluminum nitride and having the first surface 1a and the second surface 1b opposite to the first surface 1a is prepared. The ceramic plate 1 can be a ceramic precursor before sintering or a sintered ceramic; however, a sintered ceramic is preferable in that it has no dimensional change due to sintering.

In S1 of forming the through hole, the ceramic plate 1 is irradiated with the laser L so that the aluminum 11 is precipitated, to form the through hole 3 in the ceramic plate 1. The laser L is not particularly limited as long as the aluminum 11 derived from the ceramic plate 1 can be precipitated on an irradiation site 20 of the through hole 3; however, the laser L that can be thermally processed is preferable.

In the method for manufacturing the ceramic substrate according to the first embodiment, the laser L having a maximum pulse width in a pulse repetition period is a continuous wave (CW), and the pulse width of the laser L includes a continuous wave.

The pulse width of the laser L that can be thermally processed is preferably in a microsecond region or a nanosecond region, more preferably in a nanosecond region, still more preferably in a range from 1 nanosecond to 23 nanoseconds.

Examples of the laser L that can be thermally processed include a laser having an oscillation wavelength of 750 nm or more and a laser having an output of 500 W or more. Specific examples of the laser L that can be thermally processed include a fiber laser, a disk laser, and a CO₂ laser.

The pulse width, output, and wavelength of the laser L that can be thermally processed are not particularly limited, and for example, the laser L can be processed under the conditions of a fiber laser (CW: 1 nanosecond, wavelength: 532 nm, output: 1500 W), a disk laser (CW: 3 nanoseconds, wavelength: 1064 nm, output: 1000 W), a CO₂ laser (pulse: 16 nanoseconds×200 times, wavelength: 10600 nm, output conversion: 300 W to 700 W), or the like. However, the laser L is not limited to these conditions as long as the aluminum 11 is precipitated.

A predetermined region of the first surface 1a of the ceramic plate 1 is irradiated with the laser L in the Z-axis direction and thermally processed to remove ceramic mainly by melting and sublimating the irradiation site 20 absorbing the emitted laser L, thereby forming the through hole 3 penetrating from the first surface 1a to the second surface 1b. At this time, the aluminum 11 is precipitated on the irradiation site 20 of the ceramic plate 1 irradiated with the laser L. The through hole 3 can be formed by one time irradiation with the laser L, or can be formed by gradually removing the ceramic by emitting the laser L a plurality of times.

In the ceramic plate 1 irradiated with the laser L, heat generated by the irradiation with the laser L spreads not only to the irradiation site 20 with the laser L but also from the irradiation site 20 with the laser L to a peripheral site 21. Therefore, the precipitation of the aluminum 11 from the ceramic plate 1 occurs not only in the irradiation site 20 with the laser L but also in the peripheral site 21 inside the ceramic plate 1 in an X-axis direction from the irradiation site 20.

### S2: Removing Aluminum

FIG. 6C is a schematic cross-sectional view illustrating an example of removing the precipitated aluminum in the method for manufacturing the ceramic substrate according to the first embodiment.

In the method for manufacturing the ceramic substrate according to the first embodiment, “removing the precipitated aluminum 11” includes not only completely removing the precipitated aluminum 11 but also removing only the surface side of the precipitated aluminum 11 and/or partially removing the precipitated aluminum 11.

The partial removal of the precipitated aluminum 11 is not particularly limited as long as the effect of the present disclosure is not impaired; however, 70% or more of the precipitated aluminum 11 is preferably removed with respect to the total area of the inner surface 3a defining the through hole 3, 80% or more of the precipitated aluminum 11 is more preferably removed, and 90% or more of the precipitated aluminum 11 is still more preferably removed. The removal rate of the precipitated aluminum 11 can be confirmed by observing a cross section in the thickness direction of the ceramic plate 1 including a cross section of the through hole 3 with an SEM or by electrical inspection.

As for the removal of only the surface side of the precipitated aluminum 11, 50% or more of the precipitated aluminum 11 is preferably removed in the thickness direction, 70% or more of the precipitated aluminum 11 is more preferably removed, and 90% or more of the precipitated aluminum 11 is still more preferably removed. In some cases, the precipitated aluminum 11 is not formed uniformly on the entire inner surface 3a defining the through hole 3, and the aluminum nitride is exposed on a part of the inner surface 3a defining the through hole 3. The “thickness direction of the precipitated aluminum 11” means a direction from the inner surface 3a defining the through hole 3 toward the through hole 3, that is, a YX-axis direction.

The method for removing the aluminum 11 precipitated on the irradiation site 20 of the inner surface 3a defining the through hole 3 in S1 of forming the through hole is not particularly limited; however, a solvent is preferably brought into contact with the irradiation site 20 of the inner surface 3a defining the through hole 3. Examples of the method for bringing the solvent into contact with the irradiation site 20 of the inner surface 3a defining the through hole 3 include a method using etching and a method of immersing, in the solvent, the ceramic plate 1 provided with the aluminum precipitated on the irradiation site 20 of the inner surface 3a defining the through hole 3.

The solvent is not particularly limited as long as the precipitated aluminum 11 can be removed using it, and examples thereof include alkaline solvents such as sodium hydroxide, potassium hydroxide, and lithium hydroxide; and acidic solvents such as phosphoric acid, hydrochloric acid, sulfuric acid, nitric acid, and acetic acid. These can be used alone or in combination of two or more.

The temperature and time for bringing the solvent into contact with the irradiation site 20 of the inner surface 3a defining the through hole 3 are not particularly limited as long as the precipitated aluminum 11 can be removed.

When the precipitated aluminum 11 is removed from the ceramic plate 1, the inner surface 3a defining the through hole 3 is exposed, the inner surface 3a having irregularities and being roughened. At this time, the aluminum 11 precipitated on the peripheral site 21 of a site irradiated with the laser L is also removed, and a root-shaped recessed portion 21a of the inner surface 3a defining the through hole 3 is exposed. Accordingly, the aluminum nitride of the ceramic plate 1 is exposed on the inner surface 3a defining the through hole 3.

When the precipitated aluminum 11 is removed from the ceramic plate 1, burrs 12 can be generated around the opening of the through hole 3 on the first surface 1a and the second surface 1b of the ceramic plate 1.

### S2-1: Polishing or Grinding Ceramic Plate

FIG. 6D is a schematic cross-sectional view illustrating an example of polishing or grinding the ceramic plate in the method for manufacturing the ceramic substrate according to the first embodiment.

In S2-1 of polishing or grinding the ceramic plate, the burrs 12 formed on the first surface 1a and the second surface 1b of the ceramic plate 1 are polished or ground for removal. In a case in which the burrs 12 have been formed, in S2-1 of polishing or grinding the ceramic plate, the periphery of the opening of the through hole 3 is preferably made substantially flush with the first surface 1a and the second surface 1b by removing the burrs 12.

S2-1 of polishing or grinding the ceramic plate need not be performed, and the burrs 12 can be removed simultaneously with polishing or grinding of the conductive member 2 in S5 of polishing or grinding the conductive member.

### S3: Disposing Conductive Paste

FIG. 6E is a schematic cross-sectional view illustrating an example of disposing the conductive paste in the method for manufacturing the ceramic substrate according to the first embodiment. FIG. 7A is an enlarged cross-sectional view schematically illustrating a region VIIA in FIG. 6E.

In S3 of disposing the conductive paste, by filling the through hole 3 with the conductive paste 30, the conductive paste 30 can be disposed inside the through hole 3. At this time, the root-shaped recessed portion 21a is also filled with the conductive paste 30.

In S3 of disposing the conductive paste, the conductive paste 30 can be disposed by filling the through hole 3 with the conductive paste 30 by, for example, screen printing, metal mask printing, injection using a nozzle, or the like, so as to have substantially the same surface height as the first surface 1a and the second surface 1b of the ceramic plate 1.

In S3 of disposing the conductive paste, in addition to filling the through hole 3 with the conductive paste 30, the conductive paste 30 preferably covers the opening of the through hole 3 and at least a part of at least one of the first surface 1a and the second surface 1b of the ceramic plate 1. This can prevent a decrease in dimensional accuracy due to volumetric shrinkage when the conductive paste 30 is sintered in S4 of forming the conductive member.

As a specific example, when the through hole 3 is filled with the conductive paste 30 in S3 of disposing the conductive paste, the conductive paste 30 can be disposed covering the opening of the through hole 3 and at least a part of at least one of the first surface 1a and the second surface 1b of the ceramic plate 1 by filling the through hole 3 with the conductive paste 30 from the first surface 1a of the ceramic plate 1 by using, for example, a squeegee as a tool used for screen printing and by filling the through hole 3 with the conductive paste 30 from the second surface 1b of the ceramic plate 1 by using a squeegee in a manner similar to that of the first surface 1a. That is, the conductive paste 30 can be disposed covering at least a part of at least one of the first surface 1a and the second surface 1b of the ceramic plate 1 continuously from the through hole 3.

In S3 of disposing the conductive paste, after disposing the conductive paste 30 and before sintering, drying of the conductive paste 30 and pressurization of the dried conductive paste 30 are preferably further performed. In order to dry the conductive paste 30, the conductive paste 30 can be dried by being placed in an electric furnace having an atmosphere at a temperature higher than room temperature and lower than 100° C., for example. When the ceramic plate 1 provided with the conductive paste 30 is placed in the electric furnace, drying and pressurization are preferably performed at a time through a mold for pressurization. By drying and pressurizing the conductive paste 30, volumetric shrinkage of the conductive paste 30 is less likely to occur in S4 of forming the conductive member 2.

### Conductive Paste 30

The conductive paste 30 preferably includes an active metal brazing material in terms of suitably forming the nitride coating film 4 on the inner surface 3a defining the through hole 3 and improving the adhesion between the ceramic plate 1 and the conductive member 2. The active metal brazing material contains a eutectic powder 14 of silver and copper, an active metal powder 15, and a solvent 16, preferably further contains an inorganic filler 17, and further contains other components as necessary.

Note that the active metal brazing material has fluidity, can freely fill the through hole 3 having an arbitrary shape, and can be disposed by being cured after being applied in an arbitrary shape and with an arbitrary thickness.

### Eutectic Powder 14

The eutectic powder 14 is a eutectic powder of silver and copper. The melting point of the eutectic powder of silver and copper is about 780° C.

The content of the eutectic powder 14 in the conductive paste 30 is not particularly limited, but is preferably in a range from 40 mass % to 95 mass % when the total amount of the eutectic powder 14, the active metal powder 15, and the inorganic filler 17 is 100 mass %.

### Active Metal Powder 15

After sintering, the active metal powder 15 becomes a metal compound 18 disposed on at least a part of the inner surface 3a defining the through hole 3 and the surface of the inorganic filler 17.

The active metal powder 15 is not particularly limited, and examples thereof include titanium hydride (TiH₂), cerium hydride (CeH₂), zirconium hydride (ZrH₂), and magnesium hydride (MgH₂). These can be used alone or in combination of two or more. Among these, the active metal powder 15 preferably contains TiH₂. When the active metal powder 15 contains TiH₂, it reacts with the aluminum nitride exposed on the inner surface 3a defining the through hole 3 and can become titanium nitride (TiN) as the metal compound 18. Titanium nitride is known as a barrier metal. Accordingly, the migration of the metal in the conductive member 2 can be suppressed, and the ceramic substrate 100 having high reliability can be obtained.

The content of the active metal powder 15 in the conductive paste 30 is not particularly limited, but is preferably in a range from 2 mass % to 15 mass % when the total amount of the eutectic powder 14, the active metal powder 15, and the inorganic filler 17 is 100 mass %. When the content of the active metal powder 15 is 2 mass % or more with respect to the total amount of the eutectic powder 14, the active metal powder 15, and the inorganic filler 17, the nitride coating film 4 having a suitable thickness can be formed. In addition, hydrogen derived from the active metal powder 15 can bring a reaction phase into a reducing atmosphere, so that the conductive paste 30 can be suitably sintered. This is because when the content of the active metal powder 15 exceeds 15 mass % with respect to the total amount of the eutectic powder 14, the active metal powder 15, and the inorganic filler 17, it is highly possible that the generated hydrogen has not escaped and remains as a void in the conductive member 2.

### Solvent 16

The solvent 16 is not particularly limited, but is preferably an organic binder. The organic binder is not particularly limited, and examples thereof include a thermosetting resin and a thermoplastic resin. Specific examples of the organic binder include epoxy resins, silicone resins, acrylic resins, urethane resins, polyvinyl resins, ethyl cellulose resins, phenol resins, polyimide resins, polyurethane resins, melamine resins, and polyurea resins. The organic binder can be a solvent and a resin material generally used as a via material. These can be used alone or in combination of two or more. Since the organic binder serves as a sintering binder, the organic binder is decomposed, evaporated, and removed in S4 of forming the conductive member 2.

The content of the solvent 16 in the conductive paste 30 is not particularly limited and can be appropriately selected depending on the content of the eutectic powder 14, the active metal powder 15, and the inorganic filler 17.

### Inorganic Filler 17

The inorganic filler 17 is not particularly limited, and examples thereof include ceramic fillers such as silica fillers, metal fillers, and glass fillers. These can be used alone or in combination of two or more. Among these, a ceramic filler is preferable as the inorganic filler 17. When the conductive paste 30 includes the inorganic filler 17, the thermal conductivity and the heat dissipation property of the conductive member 2 can be improved.

The ceramic filler is not particularly limited, and examples thereof include aluminum nitride (AlN), silicon nitride (Si₃N₄), aluminum oxide (Al₂O₃), and silicon carbide (SiC).

In addition, the inorganic filler 17 is preferably a material having a linear expansion coefficient of 8 ppm or less. In that case, the linear coefficient of the conductive member 2 can be lowered and thermal shock characteristics can be improved.

The median diameter of the inorganic filler 17 is not particularly limited, but is preferably in a range from 1 μm to 50 μm, more preferably in a range from 2 μm to 15 μm.

The inorganic filler 17 is preferably a material having a linear expansion coefficient of 5 ppm or less and a high thermal conductivity of 100 W/m·K or more. Examples of such a material include ceramic fillers described above. By dispersing and disposing such a material in the conductive member 2, the difference in linear expansion coefficient can be reduced and reliability such as thermal shock characteristics can be improved.

The thermal conductivity of the inorganic filler 17 is not particularly limited, but is preferably 20 W/(m/K) or more, more preferably 30 W/(m/K) or more at a measurement temperature of 300 K.

The content of the inorganic filler 17 in the conductive paste 30 is not particularly limited, but is preferably in a range from 4 mass % to 50 mass % when the total amount of the eutectic powder 14, the active metal powder 15, and the inorganic filler 17 is 100 mass %.

### Other Components

The other components in the conductive paste 30 are not particularly limited, and examples thereof include a reducing agent such as an organic acid and other eutectic alloy powders other than the eutectic powder of silver and copper. These can be used alone or in combination of two or more.

Examples of the other eutectic alloy powders other than the eutectic powder of silver and copper include powders of a eutectic alloy of copper and zinc and a eutectic alloy of copper and tin. These can be used alone or in combination of two or more.

The melting points of the other eutectic alloy powders are not particularly limited, but are preferably in a range from 700° C. to 1200° C., more preferably in a range from 720° C. to 1100° C., still more preferably in a range from 780° C. to 850° C.

The contents of the other eutectic alloy powders are not particularly limited as long as the effect of the present disclosure is not impaired.

### S4: Forming Conductive Member

FIG. 6F is a schematic cross-sectional view illustrating an example of forming the conductive member in the method for manufacturing the ceramic substrate according to the first embodiment. FIG. 7B is an enlarged cross-sectional view schematically illustrating a region VIIB in FIG. 6F.

In S4 of forming the conductive member, the conductive member 2 is formed inside the through hole 3, and the nitride coating film 4 is formed on the inner surface 3a defining the through hole 3.

In S4 of forming the conductive member, the active metal brazing material as the conductive paste 30 is sintered to form the conductive member. The sintering can be performed using a sintering furnace such as an electric furnace.

The sintering temperature when the conductive paste 30 is sintered is not particularly limited, but is preferably in a range from 700° C. to 1200° C., more preferably in a range from 720° C. to 1000° C., still more preferably in a range from 750° C. to 900° C. By sintering the conductive paste 30 at a preferable sintering temperature, the eutectic of silver and copper is melted, and conduction of the conductive member 2 can be obtained.

The sintering atmosphere when the conductive paste 30 is sintered is not particularly limited, but is preferably an Ar atmosphere of 99.9% or more or a vacuum atmosphere of 10-5 Pa or less.

The sintering time when the conductive paste 30 is sintered is not particularly limited, but is preferably in a range from 5 minutes to 60 minutes, more preferably in a range from 10 minutes to 50 minutes, still more preferably in a range from 15 minutes to 45 minutes.

The conductive member 2 produced using the conductive paste 30 includes, for example, the metal compound 18, a metal 19, and the inorganic filler 17. The solvent 16 is evaporated and removed by sintering the conductive paste 30.

In the conductive member 2, for example, when the total content of the metal compound 18, the metal 19, and the inorganic filler 17 is 100 mass %, the content of the metal compound 18 is preferably in a range from 1 mass % to 10 mass %, the content of the metal 19 is preferably in a range from 40 mass % to 95 mass %, and the content of the inorganic filler 17 is preferably in a range from 4 mass % to 50 mass %. When the conductive member 2 includes the inorganic filler 17 at a predetermined ratio, volumetric shrinkage can be reduced. In addition, when the conductive member 2 includes the metal 19 at a predetermined ratio, the inorganic filler 17 can be dispersed in the metal 19 that is continuous.

The metal 19 is a metal member serving as a core of the conductive member 2 together with the inorganic filler 17 when formed for the conductive member 2. The metal 19 is disposed in a state in which the inorganic filler 17 is dispersed.

In S4 of forming the conductive member, the eutectic powder 14 of silver and copper in the conductive paste 30 is sintered to become the metal 19. Accordingly, the metal 19 includes a eutectic of silver and copper, and when the conductive paste 30 includes another metal eutectic powder, the metal 19 further includes the metal eutectic.

The inorganic filler 17 is disposed in the conductive member 2 in a state in which a plurality of particles thereof are dispersed. A plurality of inorganic fillers 17 indicate that the inorganic filler 17 is not one particle but a plurality of particles.

The inorganic filler 17 is preferably disposed in a range from 10 μm² to 75 μm² per 100 μm² in cross-sectional view in the Z-axis direction b of the conductive member 2.

The metal compound 18 is formed by sintering the active metal powder 15. By sintering the conductive paste 30, a reaction phase of the inorganic filler 17 and the active metal powder 15 is formed on the surface of the inorganic filler 17. The metal compound 18 is mainly disposed on at least a part or all of the surface of the inorganic fillers 17 and at least a part of the inner surface 3a defining the through hole 3. The metal compound 18 includes a filler-surface metal compound 18a disposed on the surface of the inorganic filler 17 and a wall-surface metal compound 18b disposed on at least a part of the inner surface 3a defining the through hole 3. Preferably, components of the active metal powder 15, the inorganic filler 17, and the inner surface 3a defining the through hole 3 are sintered, so that the filler-surface metal compound 18a and the wall-surface metal compound 18b are disposed as reaction products.

The filler-surface metal compound 18a is the metal compound 18 and covers at least a part or all of the surface of the inorganic filler 17. For example, when the inorganic filler 17 is aluminum nitride (AlN) or silicon nitride (Si₃N₄), the filler-surface metal compound 18a is formed on the surface of the inorganic filler 17 as titanium nitride (TiN) by reaction between the inorganic filler 17 and titanium hydride (TiH₂) of the active metal powder 15 before sintering, for example. The filler-surface metal compound 18a is provided, on the surface thereof, with continuous jagged irregularities, and the inorganic filler 17 is also provided, on the surface thereof, with jagged irregularities. The inorganic fillers 17 each having a surface provided with the filler-surface metal compound 18a are dispersed in the conductive member 2 that is continuous.

The wall-surface metal compound 18b is disposed as the metal compound 18 on at least a part of the inner surface 3a defining the through hole 3. Since the inner surface 3a defining the through hole 3 includes silicon nitride, when the active metal powder 15 before sintering is, for example, titanium hydride, a reaction product is generated and the wall-surface metal compound 18b is formed as a compound on the inner surface 3a defining the through hole 3, for example. The wall-surface metal compound 18b is continuously formed, with the surface thereof having jagged irregularities, on the inner surface 3a defining the through hole 3. The wall-surface metal compound 18b is also formed in the root-shaped recessed portion of the inner surface 3a defining the through hole 3, thereby forming the nitride coating film 4. This can improve the adhesion between the conductive member 2 and the inner surface 3a defining the through hole 3. In addition, heat transmitted from the conductive member 2 to the ceramic included in the ceramic plate 1 via the inner surface 3a defining the through hole 3 can be efficiently released.

In this way, the ceramic substrate 100 including the ceramic plate 1 and the conductive member 2 provided with the nitride coating film 4 on the inner surface 3a defining the through hole 3 is obtained. The average thickness of the nitride coating film 4 in the ceramic substrate 100 is preferably in a range from 10 μm to 35 μm, more preferably in a range from 10 μm to 25 μm.

### S5: Polishing or Grinding Conductive Member

FIG. 6G is a schematic cross-sectional view illustrating an example of polishing or grinding the conductive member in the method for manufacturing the ceramic substrate according to the first embodiment.

In S5 of polishing or grinding the conductive member, the conductive member 2 is polished or ground so that at least one of the first surface 1a and the second surface 1b of the ceramic plate 1 in the portion covered with the conductive member 2 is exposed.

The ceramic substrate 100 obtained in S4 of forming the conductive member can be used as is, for example, when only the through hole 3 of the ceramic plate 1 is filled with the conductive paste 30 in S3 of disposing the conductive paste; however, for example, when the conductive paste 30 is disposed covering the opening of the through hole 3 and at least a part of at least one of the first surface 1a and the second surface 1b of the ceramic plate 1, S5 of polishing or grinding the conductive member is further performed, so that the first surface 1a and the second surface 1b of the ceramic plate 1 and the surface (exposed surface) of the conductive member 2 can be made substantially flush with each other.

In S4 of forming the conductive member, the first surface 1a and the second surface 1b of the ceramic plate 1 is blackened in some cases, but the blackening can be removed in S5 of polishing or grinding the conductive member.

### First Modified Example of First Embodiment

The first modified example of the method for manufacturing the ceramic substrate according to the first embodiment is different from the method for manufacturing the ceramic substrate according to the first embodiment in that the laser L is emitted such that the opening diameter of the through hole 3 on the first surface 1a of the ceramic plate 1 is larger than the opening diameter of the through hole 3 on the second surface 1b in S1 of forming the through hole.

The cross-sectional shape of the through hole 3 can be adjusted to a desired shape by changing the pulse width of the laser L and, as necessary, the output of the laser L. For example, as compared with the method for manufacturing the ceramic substrate according to the first embodiment, the output of the laser L can be reduced or the time for irradiation with the laser L can be shortened. The laser Lis preferably emitted from the first surface 1a side of the ceramic plate 1.

### Second Embodiment

A method for manufacturing the ceramic substrate according to the second embodiment is different from the method for manufacturing the ceramic substrate according to the first embodiment in that SIA of forming the recessed portion 5 in the ceramic plate 1 is performed instead of forming the through hole 3 in the ceramic plate 1 in S1 of forming the through hole.

The recessed portion 5 can be formed and the depth of the recessed portion 5 can also be adjusted by changing the pulse width of the laser L and, as necessary, the output thereof. For example, as compared with the method for manufacturing the ceramic substrate according to the first embodiment, the output of the laser L can be reduced or the time for irradiation with the laser L can be shortened.

### First Modified Example of Second Embodiment

A first modified example of the method for manufacturing the ceramic substrate according to the second embodiment is different from the method for manufacturing the ceramic substrate according to the second embodiment in that the laser Lis emitted such that the opening diameter of the recessed portion 5 on the first surface 1a of the ceramic plate 1 is larger than the bottom diameter of the recessed portion 5 in SIA of forming the recessed portion 5 in the ceramic plate 1.

The cross-sectional shape of the recessed portion 5 can be adjusted to a desired shape by changing the pulse width of the laser L and, as necessary, the output thereof. For example, as compared with the method for manufacturing the ceramic substrate according to the second embodiment, the output of the laser L can be reduced or the time for irradiation with the laser L can be shortened.

### Second Modified Example of First Embodiment or Second Embodiment

A second modified example of the method for manufacturing the ceramic substrate according to the first embodiment or the method for manufacturing the ceramic substrate according to the second embodiment is different from the method for manufacturing the ceramic substrate according to the first embodiment or the method for manufacturing the ceramic substrate according to the second embodiment in that the conductive paste 30 further contains at least one kind of powder 31 selected from the group consisting of a copper powder, a silver powder, a powder of an alloy of silver and copper, and a ceramic powder.

The content of the at least one powder 31 selected from the group consisting of the copper powder, the silver powder, the powder of an alloy of silver and copper, and the ceramic powder in the conductive paste 30 is not particularly limited as long as the effect of the present disclosure is not impaired, but is preferably in a range from 5 mass % to 20 mass % when the total amount of the eutectic powder 14, the active metal powder 15, the inorganic filler 17, and the powder 31 is 100 mass %.

The copper powder, the silver powder, and the powder of an alloy of silver and copper are more excellent in conductivity than the eutectic powder of silver and copper. In addition, since the copper powder has a melting point of 1084° C. and the silver powder has a melting point of 962° C., the copper powder and the silver powder are not easily melted in the conductive paste 30 during sintering in S4 of forming the conductive member and can be present in a state of being dispersed as powder in the conductive member 2. This can further improve the conductivity of the ceramic substrate 100.

In addition, since the ceramic powder also has a high melting point, the ceramic powder is not easily melted in the conductive paste 30 during sintering in S4 of forming the conductive member and can be present in a state of being dispersed as powder in the conductive member 2. This can reduce a difference between the linear expansion coefficients of the ceramic plate 1 and the conductive member 2, and further improve the reliability of the ceramic substrate 100.

### Light-Emitting Device

A light-emitting device 200 according to an embodiment includes the ceramic substrate 100 according to the embodiment and a light-emitting element 202 disposed over the ceramic substrate 100 and including an electrode 205, and the electrode 205 and the conductive member 2 are electrically connected to each other.

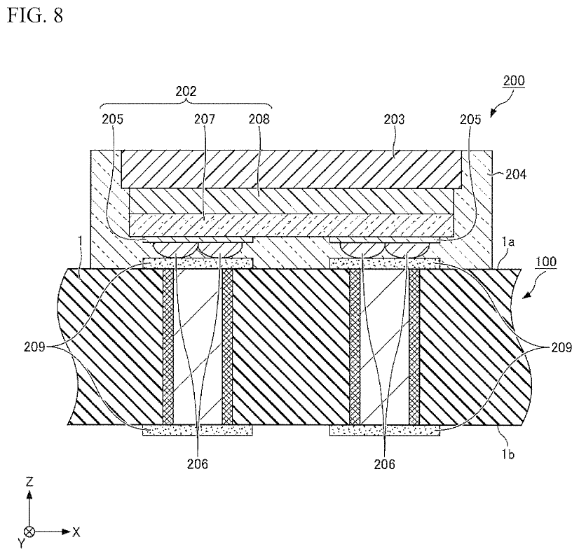

FIG. 8 is a schematic cross-sectional view illustrating an example of the light-emitting device 200 according to the embodiment. Components of the light-emitting device 200 are described below.

The light-emitting device 200 is a device in which the light-emitting element 202 is disposed on the ceramic substrate 100 so that the device can emit light. The number of light-emitting elements 202 can be either one or more than one. When a plurality of light-emitting elements 202 are provided, the arrangement of the light-emitting elements 202 is not particularly limited, and, for example, the light-emitting elements 202 can be arranged in a line.

In the light-emitting device 200, a light-transmissive member 203 covering a light extraction surface of the light-emitting element 202, a light-reflective member 204 covering a lateral surface of the light-emitting element 202 and the first surface 1a of the ceramic plate 1 of the ceramic substrate 100, and metal bumps 206 electrically connecting the light-emitting element 202 and the conductive member 2 of the ceramic substrate 100 are disposed, for example.

In the ceramic substrate 100, various patterns of wiring can be formed depending on the application. However, in the light-emitting device 200 according to the embodiment, the light-emitting element 202 is provided with a pair of electrodes 205 on the same surface side, and is mounted face-down with the surface provided with the electrodes 205 facing the first surface 1a of the ceramic plate 1 in the ceramic substrate 100.

The light-emitting device 200 according to the embodiment can be face-up mounted, where the pair of electrodes 205 of the light-emitting element 202 are placed on the side opposite to the surface in contact with the ceramic substrate 100 and connected to the conductive member 2 of the ceramic substrate 100 by a wire.

### Light-Emitting Element 202

The light-emitting element 202 includes the pair of electrodes 205, a semiconductor layered body 207, and an element substrate 208.

For example, the light-emitting element 202 includes the semiconductor layered body 207 on the bottom surface side of the element substrate 208, and includes the pair of electrodes 205 on the semiconductor layered body 207 side.

The semiconductor layered body 207 can employ any composition in accordance with a desired emission wavelength, and can use, for example, a nitride semiconductor (InₓAl_{y}Ga_{1-x-y}N, 0≤X, 0≤Y, X+Y≤1) or GaP, which can emit blue or green light, or GaAlAs or AlInGaP, which can emit red light. These can be used alone or in combination of two or more. The size and the shape of the light-emitting element 202 can be appropriately selected in accordance with the purpose of use.

As an example, a sapphire substrate or a silicon substrate is used as the element substrate 208.

The electrodes 205 are each connected to a corresponding one of the conductive members 2 of the ceramic substrate 100 by the metal bumps 206 via a bonding member 209. One of the electrodes 205 is a p-electrode, and the p-electrode is disposed at a distance from an n-electrode, which is the other electrode 205, so as not to be electrically short-circuited therewith. As an example, the electrodes 205 have a configuration in which one p-electrode and one n-electrode are disposed, but can have a configuration in which one of the p-electrode and the n-electrode is disposed at two positions and the other is disposed at one position.

### Light-Transmissive Member 203

The light-transmissive member 203 is disposed on a flat surface side of the element substrate 208, which serves as a light extraction surface. For example, the light-transmissive member 203 is made of a light-transmissive resin material, and an epoxy resin, a silicone resin, or a resin in which an epoxy resin and a silicone resin are mixed can be used. The light-transmissive member 203 can include a phosphor, and for example, when the light-transmissive member 203 includes a phosphor that absorbs blue light from the light-emitting element 202 and emits yellow light, white light can be emitted from the light-emitting element 202. The light-transmissive member 203 can further include a plurality of types of phosphors, and for example, even when the light-transmissive member 203 includes a phosphor that absorbs blue light from the semiconductor layered body 207 and emits green light and a phosphor that emits red light, white light can be emitted from the light-emitting element 202.

Examples of the phosphor include an yttrium aluminum garnet-based phosphor (Y₃ (Al,Ga)₅O₁₂:Ce, for example), a lutetium aluminum garnet-based phosphor (Lu₃(Al,Ga)₅O₁₂:Ce, for example), a terbium aluminum garnet-based phosphor (Tb₃(Al,Ga)₅O₁₂:Ce, for example), nitride phosphors, such as a β-SiAlON phosphor ((Si,Al)₃(O,N)₄:Eu, for example), an α-SiAlON phosphor (Mz(Si,Al)₁₂(O,N)₁₆ (where 0<z≤2, and M is Li, Mg, Ca, Y, or a lanthanide element excluding La and Ce)), a CASN-based phosphor (CaAlSiN₃:Eu, for example), and an SCASN-based phosphor ((Sr,Ca)AlSiN₃:Eu, for example), fluoride phosphors, such as a KSF-based phosphor (K₂SiF₆:Mn, for example), a KSAF-based phosphor (K₂(Si,Al)F₆:Mn, for example), and an MGF-based phosphor (3.5MgO·0.5MgF₂·GeO₂:Mn, for example), quantum dot phosphors, such as perovskite and chalcopyrite, and the like.

### Metal Bumps 206

The metal bumps 206 are a member that electrically connects the electrode 205 and the conductive member 2. The metal bumps 206 can be disposed either on the electrode 205 side or on the conductive member 2 side. The shape, size, and number of the metal bumps 206 can be appropriately set as long as they can be disposed within the range of the electrode 205. The size of the metal bumps 206 can be appropriately adjusted according to the size of the semiconductor layered body 207, the required light emission output of the light-emitting element, and the like. For example, the metal bumps 206 can have a diameter of about several tens of μm to several hundreds of μm.

The metal bumps 206 can be made of, for example, Au, Ag, Cu, Al, Sn, Pt, Zn, Ni, or an alloy thereof. The metal bumps 206 can be formed of, for example, stud bumps known in the art. The stud bumps can be formed by a stud bump bonder, a wire bonding apparatus, or the like. The metal bumps 206 can also be formed by a method known in the art such as electroplating, electroless plating, vapor deposition, or sputtering.

For example, the metal bumps 206 are bonded via the bonding member 209. Examples of the bonding member 209 used herein include solders such as tin-bismuth based solders, tin-copper based solders, tin-silver based solders, and gold-tin based solders, eutectic alloys such as alloys containing Au and Sn as main components, alloys containing Au and Si as main components, and alloys containing Au and Ge as main components, paste materials of silver, gold, palladium, and the like, anisotropic conductive materials such as ACP and ACF, brazing materials made from low melting point metals, and conductive adhesives and conductive composite adhesives of a combination of any of these.

### Light-Reflective Member 204

The light-reflective member 204 is a member having light reflectivity. The light-reflective member 204 covers the first surface 1a of the ceramic plate 1 in the ceramic substrate 100 and covers the lateral surface of the light-emitting element 202. The light-reflective member 204 exposes the light extraction surface of the light-emitting element 202 and is flush with the light-transmissive member 203 of the light-emitting element 202. For example, the light-reflective member 204 is also disposed between the lower surface of the light-emitting element 202 and the first surface 1a of the ceramic plate 1 in the ceramic substrate 100.

The light-reflective member 204 preferably has a high reflectance in order to effectively use light from the light-emitting element 202. The light-reflective member 204 is preferably white. The reflectance of the light-reflective member 204 is, for example, preferably 90% or more, more preferably 94% or more at the wavelength of the light emitted from the light-emitting element 202.

Examples of a resin used for the light-reflective member 204 include thermoplastic resins such as acrylic resin, polycarbonate resin, cyclic polyolefin resin, polyethylene terephthalate resin, polyethylene naphthalate resin, and polyester resin, and thermosetting resins such as epoxy resin and silicone resin. As a light-diffusing material, for example, a well-known material, such as titanium oxide, silicon oxide, aluminum oxide, zinc oxide, or glass, can be used.

Although the light-emitting device 200 uses one light-emitting element 202 as one unit to control brightness and turning on/off, the number of light-emitting elements 202 included in one unit can be either one or more than one. For example, four light-emitting elements 202 arranged in one row and four columns or two rows and two columns, or nine light-emitting elements 202 arranged in three rows and three columns can be used as one unit, and the number of light-emitting elements 202 is not limited.

### Application Example of Light-Emitting Device

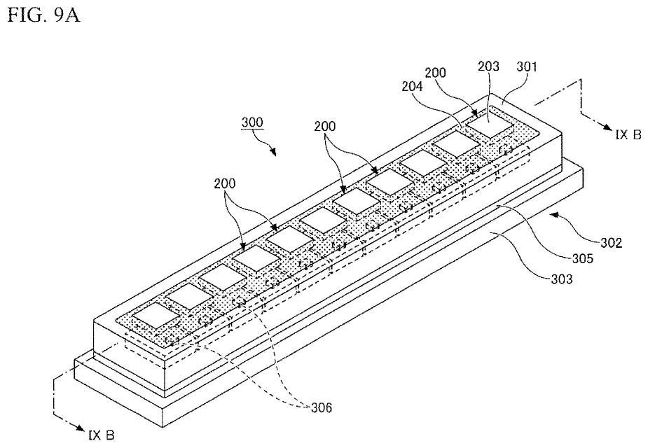

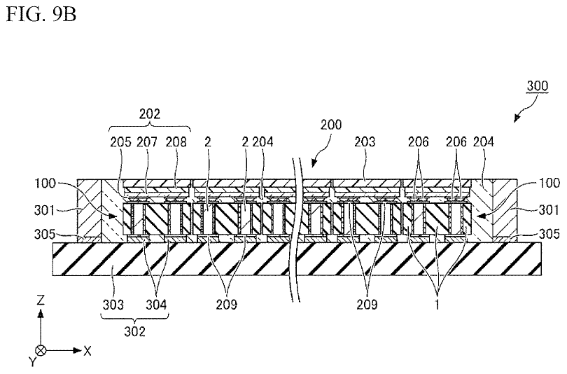

FIG. 9A is a perspective view illustrating an application example of the light-emitting device according to the embodiment. FIG. 9B is a cross-sectional view illustrating a cross section taken along line IXB-IXB in FIG. 9A. FIG. 9B does not illustrate a part of the configurations in FIG. 9A.

A light-emitting module 300 including a plurality of (eleven in FIG. 9A) light-emitting devices 200 in a line can be used, and eleven light-emitting devices 200 can be mounted on one ceramic substrate 100. A configuration of the light-emitting module 300 is described below.

The light-emitting module 300 includes eleven light-emitting devices 200 in a line, is provided with the light-reflective member 204 on the outer periphery of the light-emitting devices 200, and is provided with a frame body 301 on the outside of the light-reflective member 204, and a module substrate 302 is connected to a surface opposite to the first surface 1a of the ceramic plate 1 in the ceramic substrate 100.

The frame body 301 is a member for surrounding the light-reflective member 204 that covers the plurality of light-emitting devices 200. The frame body 301 is formed in a rectangular annular shape that is, for example, rectangular in plan view, and surrounds the periphery of the light-reflective member 204.

The frame body 301 can be formed using a member having a frame shape and made of a metal, an alloy, or a ceramic. Examples of the metal include Fe, Cu, Ni, Al, Ag, Au, Pt, Ti, W, and Pd. Examples of the alloy include an alloy including at least one selected from the group consisting of Fe, Cu, Ni, Al, Ag, Au, Pt, Ti, W, and Pd.

A resin material can be used as the frame body 301. In this case, the metal, the alloy, or the ceramic member can be embedded in the frame body 301 made of the resin material, or a part of the frame body 301 can be made of a resin material and another part thereof can be made of a metal, an alloy, or a ceramic member.

The module substrate 302 is a member on which the light-emitting device 200 is mounted, and electrically connects the light-emitting device 200 to the outside. The module substrate 302 is formed in a substantially rectangular shape in plan view, for example. The module substrate 302 includes a substrate portion 303 and wiring board portions 304.

As a material of the substrate portion 303, for example, an insulating material is preferably used, and a material that does not easily transmit light emitted from the light-emitting element 202, external light, and the like is preferably used. Examples of the material of the substrate portion 303 that can be used include ceramics such as aluminum oxide, aluminum nitride, and mullite, thermoplastic resins such as polyamide, polyphthalamide, polyphenylene sulfide, and liquid crystal polymer, and resins such as an epoxy resin, a silicone resin, a modified epoxy resin, a urethane resin, and a phenol resin. Among these, as the material of the substrate portion 303, a ceramic, having excellent heat dissipation characteristics, is preferably used.

The wiring board portion 304 is formed on the substrate portion 303 at a position facing the conductive member 2 on the surface of the ceramic substrate 100 of the light-emitting device 200 opposite to the first surface 1a of the ceramic plate 1. Examples of a material of the wiring board portion 304 include those exemplified as the material used for the conductive member 2.

Note that the module substrate 302 is bonded to the frame body 301 via a conductive adhesive 305, and is disposed such that the conductive member 2 and the wiring board portion 304 are bonded to each other. As the conductive adhesive 305, for example, a eutectic solder, a conductive paste, a bump, or the like can be used. In the light-emitting device 200, a protective element 306 is disposed on the ceramic substrate 100 in parallel with each light-emitting element 202.

Since the light-emitting module 300 is configured as described above, the light-emitting module 300 is driven as follows. That is, in the light-emitting module 300, a current is supplied from an external power supply to the light-emitting elements 202 via the wiring board portions 304, the conductive member 2, and the electrodes 205, so that the light-emitting elements 202 emit light. Of the light emitted from the light-emitting element 202, light traveling upward is extracted to the outside above the light-emitting device 200 via the light-transmissive member 203. Light traveling downward is reflected by the ceramic substrate 100 and is extracted to the outside of the light-emitting device 200 via the light-transmissive member 203. Light traveling between the light-emitting element 202 and the frame body 301 is reflected by the light-reflective member 204 and the frame body 301 and is extracted to the outside of the light-emitting device 200 via the light-transmissive member 203. Light traveling between the light-emitting elements 202 is reflected by the light-reflective member 204 and is extracted to the outside of the light-emitting device 200 via the light-transmissive member 203. At this time, when a space between the light-transmissive members 203 is narrow (for example, equal to or less than 0.2 mm), for example, and the light-emitting module 300 is used for a light source of a vehicle headlight, a configuration of an optical system can be simplified and reduced in size.

Note that when the light-emitting module 300 is manufactured, the light-emitting devices 200 are arranged on a sheet member, the frame body 301 is disposed around the light-emitting devices 200, and a space surrounded by the frame body 301 and the sheet member is filled with the light-reflective member 204 in this state, so that the light-reflective member 204 is disposed. Subsequently, by disposing the light-emitting devices 200 supported by the frame body 301 and the light-reflective member 204 on the module substrate 302 on which the wiring board portions 304 and the conductive adhesive 305 are disposed and electrically connecting the conductive members 2 and the wiring board portions 304, the light-emitting module 300 is manufactured.

### Method for Manufacturing Light-Emitting Device

A method for manufacturing the light-emitting device according to the embodiment includes preparing the ceramic substrate 100 manufactured by the method for manufacturing the ceramic substrate 100 according to the embodiment, and disposing the light-emitting element 202 including the electrodes 205 on the ceramic substrate 100, and each of the electrodes 205 and a corresponding one of the conductive members 2 are electrically connected to each other.

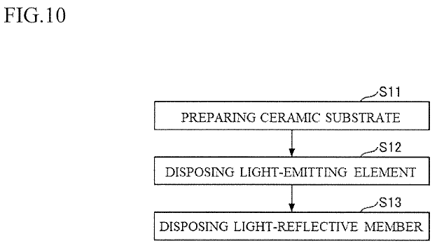

FIG. 10 is a flowchart showing an example of the method for manufacturing the light-emitting device according to the embodiment. The method for manufacturing the light-emitting device according to the embodiment includes, for example, disposing the light-reflective member.

### S11: Preparing Ceramic Substrate

In S11 of preparing the ceramic substrate 100, the ceramic substrate 100 according to the embodiment is prepared.

Note that the ceramic substrate 100 can include a plurality of regions in which the light-emitting elements 202 are disposed, and can have a size for singulation to separate the light-emitting devices 200 after the light-reflective member 204 is disposed, or the ceramic substrate 100 can have a size for each light-emitting device 200.

### S12: Disposing Light-Emitting Element

In S12 of disposing the light-emitting element, the light-emitting element 202 provided with the electrodes 205 is disposed over the ceramic substrate 100. In S12 of disposing the light-emitting element, the electrodes 205 of the light-emitting element 202 are connected to the bonding members 209 disposed on the conductive members 2 by using the metal bumps 206. Note that the light-emitting element 202 is disposed in a state in which the light-transmissive member 203 is connected to the element substrate 208 in advance. When the light-transmissive member 203 is bonded to the element substrate 208, a light-transmissive bonding material is used.

### S13: Disposing Light-Reflective Member

In S13 of disposing the light-reflective member, the light-reflective member 204 is disposed covering the first surface 1a of the ceramic plate 1 of the ceramic substrate 100 and the lateral surface of the light-emitting element 202. The light-reflective member 204 is disposed on the ceramic substrate 100 so as to surround the light-emitting element 202 and expose the upper surface of the light-transmissive member 203 serving as the light extraction surface of the light-emitting element 202. The light-reflective member 204 is disposed so as to have a rectangular shape in plan view.

In the method for manufacturing the light-emitting device according to the embodiment, a singulation operation is performed as necessary after S13 of disposing the light-reflective member. For the light-emitting device 200, one unit of the light-emitting device 200 is set in advance by the number of the light-emitting elements 202 used. Therefore, when a plurality of the light-emitting devices 200 are manufactured at a time, the singulation operation is performed. When the singulation operation is performed, the plurality of light-emitting devices 200 are manufactured by performing cutting in a lattice pattern. Examples of the cutting method include methods using a rotating blade having a disk shape, an ultrasonic cutter, and a laser light irradiation blade.

### EXAMPLES

The present invention is specifically described below through examples; however, the present invention is not limited to these examples.

### First Example

The conductive paste 30 was prepared by mixing 84 parts by mass of eutectic powder of silver and copper, 10 parts by mass of titanium hydride powder, 1 part by mass of polyvinyl butyral (PVB) resin, and 5 parts by mass of aluminum nitride powder. Using the conductive paste 30, the ceramic substrate 100 was manufactured by the method for manufacturing the ceramic substrate according to the embodiment on the basis of the flowchart shown in FIG. 5. In S1 of forming the through hole, a fiber laser (CW: 1 nanosecond, wavelength: 532 nm, power: 1500 W) was used. In S4 of forming the conductive member, the ceramic plate 1 in which the conductive paste 30 was disposed in the through hole 3 was sintered at 850° C. for 30 minutes.

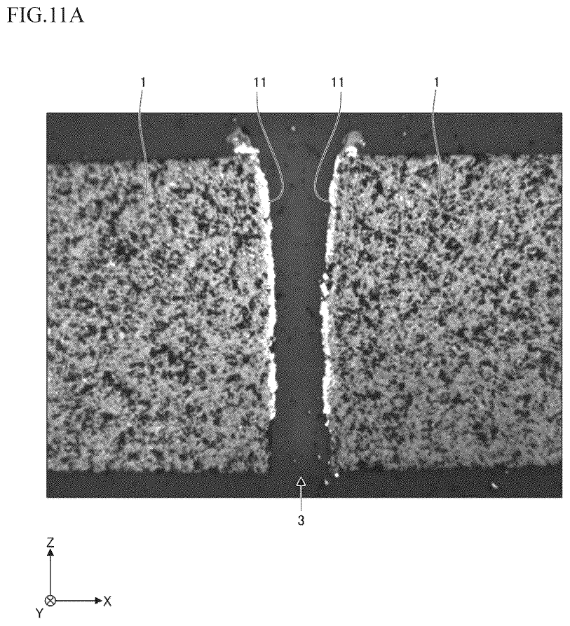

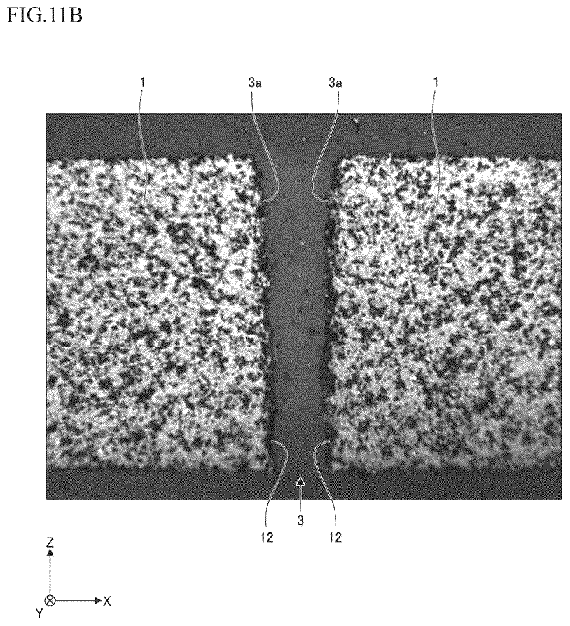

After S1 of forming the through hole and S2 of removing the aluminum, the ceramic plate 1 was cut in the thickness direction by laser irradiation and observed with a metallurgical microscope at a magnification of 250 times. FIG. 11A shows a cross-sectional observation image of the through hole 3 after irradiation with the laser L in S1 of forming the through hole. The aluminum 11 precipitated on the inner surface defining the through hole 3 was observed. FIG. 11B shows a cross-sectional observation image of the through hole 3 after etching in S2 of removing the aluminum. It was confirmed that the precipitated aluminum 11 was removed and the burrs 12 were generated on the inner surface 3a defining the through hole 3.

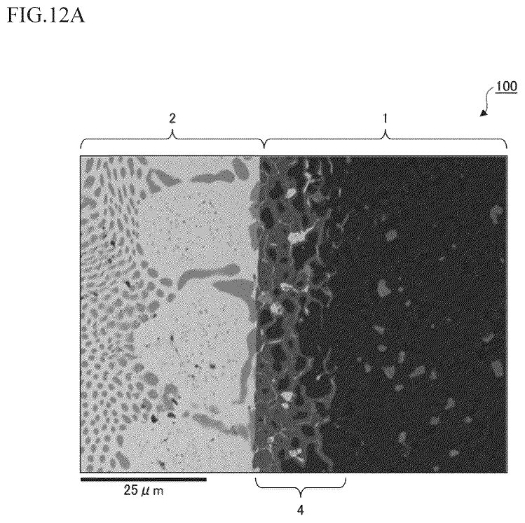

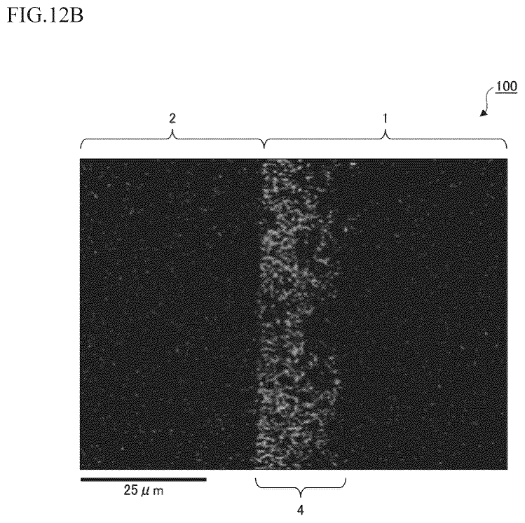

The manufactured ceramic substrate 100 was cut in the thickness direction by laser beam irradiation. A region including the inner surface 3a defining the through hole 3 in the cut cross section was observed with an SEM at a magnification of 250 times. FIG. 12A shows an observation image of a cross section of the ceramic substrate 100 with an SEM. FIG. 12B shows a fluorescent X-ray spectroscopic image (Ti-Kα) of a cross section of the ceramic substrate 100 as an observation image thereof.

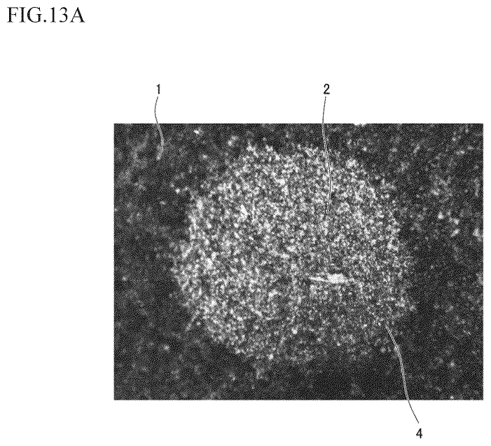

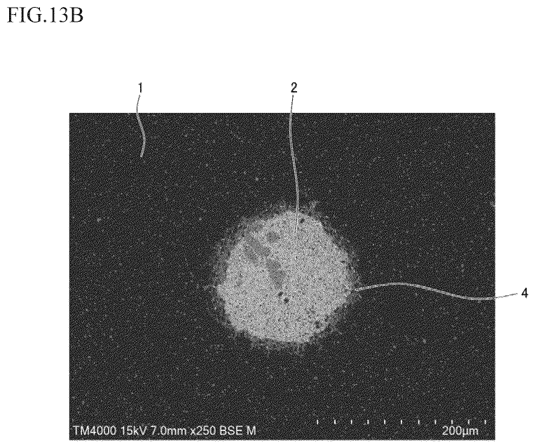

In addition, the region including the inner surface 3a defining the through hole 3 on the first surface 1a of the manufactured ceramic substrate 100 was observed with a metallurgical microscope and an SEM at a magnification of 250 times. FIG. 13A shows an observation image of the region including the inner surface 3a defining the through hole 3 in the first surface 1a of the ceramic substrate 100 by a metallurgical microscope. FIG. 13B shows an SEM observation image of the region including the inner surface 3a defining the through hole 3 in the first surface 1a of the ceramic substrate 100 in the cross section of the ceramic substrate 100.

From these observation images, the inner surface 3a defining the root-shaped through hole 3 and the nitride coating film 4 including the nitride present in the inner surface 3a were confirmed. The average thickness of the nitride coating film 4 was 20 μm, and the opening diameter of the through hole 3 was 100 μm.

As described above, the present invention has been described based on specific embodiments, but these are merely presented as examples, and the present invention is not limited by the above-described embodiments. The above embodiments can be embodied in various other forms, and various combinations, omissions, substitutions, additions, modifications, and the like can be made without departing from the spirit of the invention. These embodiments and variations thereof are included in the scope and spirit of the invention and are within the scope of the invention described in the claims and equivalents thereof.

1. A method for manufacturing a ceramic substrate, comprising:
forming a through hole or a recessed portion in a ceramic plate containing aluminum nitride by irradiating the ceramic plate with a laser so that aluminum is precipitated;
removing the aluminum precipitated on an inner surface of the through hole or the recessed portion; and
disposing a conductive paste inside the through hole or the recessed portion.

2. The method for manufacturing a ceramic substrate, according to claim 1, wherein
in the disposing of the conductive paste, the conductive paste is an active metal brazing material, and
the method comprises forming a conductive member by filling the inside of the through hole or the recessed portion with the active metal brazing material and then sintering the active metal brazing material.

3. The method for manufacturing a ceramic substrate, according to claim 2, wherein
the ceramic plate has a first surface and a second surface opposite to the first surface, and
in the disposing of the conductive paste, the conductive paste is disposed covering an opening of the through hole or the recessed portion and at least a part of at least one of the first surface and the second surface of the ceramic plate.

4. The method for manufacturing a ceramic substrate, according to claim 2, wherein the active metal brazing material contains a eutectic powder of silver and copper, an active metal, and a solvent.

5. The method for manufacturing a ceramic substrate, according to claim 4, wherein the active metal brazing material further contains at least one powder selected from the group consisting of a copper powder, a silver powder, a powder of an alloy of silver and copper, and a ceramic powder.

6. The method for manufacturing a ceramic substrate, according to claim 4, wherein a content of the active metal in the active metal brazing material is in a range from 2 mass % to 15 mass %.

7. The method for manufacturing a ceramic substrate, according to claim 3, wherein the forming of the conductive member comprises polishing or grinding the conductive member so that at least one of the first surface and the second surface of the ceramic plate in a portion covered with the conductive member is exposed.

8. The method for manufacturing a ceramic substrate, according to claim 1, wherein the removing of the aluminum further comprises bringing a solvent into contact with the inner surface of the through hole or the recessed portion.

9. The method for manufacturing a ceramic substrate, according to claim 1, wherein the ceramic plate has a first surface and a second surface opposite to the first surface, and
in the forming of the through hole or the recessed portion, an opening diameter of the through hole formed in the first surface of the ceramic plate is larger than an opening diameter of the through hole formed in the second surface.

10. The method for manufacturing a ceramic substrate, according to claim 2, wherein in the forming of the conductive member, an average thickness of a nitride coating film formed on the inner surface defining the through hole or the recessed portion is in a range from 10 μm to 35 μm.

11. The method for manufacturing a ceramic substrate, according to claim 1, wherein in the forming of the through hole or the recessed portion, the ceramic plate is thermally processed by irradiation with the laser to precipitate the aluminum on the inner surface of the through hole or the recessed portion.

12. The method for manufacturing a ceramic substrate, according to claim 11, wherein the laser is a laser having an oscillation wavelength of 750 nm or more or a laser having an output of 500 W or more.

13. The method for manufacturing a ceramic substrate, according to claim 1, wherein in the forming of the through hole or the recessed portion, the ceramic plate is a sintered ceramic plate.

14. A method for manufacturing a light-emitting device, comprising:
preparing the ceramic substrate manufactured by the method for manufacturing a ceramic substrate according to claim 2; and
disposing a light-emitting element comprising an electrode over the ceramic substrate, wherein
the electrode and the conductive member are electrically connected to each other.

15. A ceramic substrate comprising:
a ceramic plate containing aluminum nitride and having a first surface, a second surface opposite to the first surface, and a through hole connecting the first surface and the second surface or a recessed portion in at least one of the first surface and the second surface; and
a conductive member formed inside the through hole or the recessed portion,
wherein in the through hole or the recessed portion, an inner surface defining the through hole or the recessed portion is provided with a nitride coating film having an average thickness in a range from 10 μm to 35 μm.

16. The ceramic substrate according to claim 15, wherein the conductive member contains a eutectic structure of silver and copper.

17. The ceramic substrate according to claim 16, wherein the conductive member further contains at least one powder selected from the group consisting of a copper powder, a silver powder, a powder of an alloy of silver and copper, and a ceramic powder.

18. The ceramic substrate according to claim 15, wherein the inner surface defining the through hole or the recessed portion is provided with the nitride coating film that is discontinuous and is not provided with a continuous aluminum film.

19. The ceramic substrate according to claim 15, wherein the inner surface defining the through hole or the recessed portion is provided with the nitride coating film that is continuous.

20. A light-emitting device comprising:
the ceramic substrate according to claim 15; and
a light-emitting element disposed over the ceramic substrate and comprising an electrode, wherein
the electrode and the conductive member are electrically connected to each other.
